(19) United States
(12) Patent Application Publication
(10) Pub. No.: US 2015/0084063 A1
(43) Pub. Date: Mar. 26, 2015

(54) SEMICONDUCTOR DEVICE WITH A CURRENT SPREADING LAYER

(71) Applicant: Cree, Inc., Durham, NC (US)

(72) Inventors: Edward Robert Van Brunt, Raleigh, NC (US); Vipindas Pala, Morrisville, NC (US); Lin Cheng, Chapel Hill, NC (US); Qingchun Zhang, Cary, NC (US)

(73) Assignee: Cree, Inc., Durham, NC (US)

(21) Appl. No.: 14/255,611

(22) Filed: Apr. 17, 2014

Related U.S. Application Data
(63) Continuation-in-part of application No. 14/032,718, filed on Sep. 20, 2013.

(51) Int. Cl. H01L 29/872; H01L 29/66

(52) U.S. Cl. CPC H01L 29/8725; H01L 29/66143
USPC 257/77; 438/478

(57) ABSTRACT

A semiconductor device includes a substrate, a drift layer over the substrate, a spreading layer over the drift layer, and a pair of junction implants in a surface of the spreading layer opposite the drift layer. An anode covers the surface of the spreading layer opposite the drift layer, and a cathode covers a surface of the substrate opposite the drift layer. By including the spreading layer, a better balance can be struck between the on state resistance of the semiconductor device and the peak electric field in the device, thereby improving the performance thereof.

### RELATED APPLICATIONS

This application is a continuation-in-part of U.S. patent application Ser. No. 14/032,718, filed Sep. 20, 2013, the disclosure of which is hereby incorporated herein by reference in its entirety. This application is related to concurrently filed U.S. patent application Ser. No. ______ entitled “MONOLITHICALLY INTEGRATED VERTICAL POWER TRANSISTOR AND BYPASS DIODE,” which is incorporated herein by reference in its entirety.

### FIELD OF THE DISCLOSURE

The present disclosure relates to power transistors including an integrated bypass diode.

### BACKGROUND

Power transistor devices are often used to transport large currents and support high voltages. One example of a power transistor device is the power metal-oxide-semiconductor field-effect transistor (MOSFET). A power MOSFET has a vertical structure, wherein a source contact and a gate contact are located on a first surface of the MOSFET device that is separated from a drain contact by a drift layer formed on a substrate. Vertical MOSFETs are sometimes referred to as vertical diffused MOSFETs (VDMOS) or double-diffused MOSFETs (DMOSFETs). Due to their vertical structure, the voltage rating of a power MOSFET is a function of the doping level and thickness of the drift layer. Accordingly, high voltage power MOSFETs may be achieved with a relatively small footprint.

FIG. 1 shows a conventional power MOSFET device 10. The conventional power MOSFET device 10 includes an N-doped substrate 12, an N-doped drift layer 14 formed over the substrate 12, one or more junction implants 16 in the surface of the drift layer 14 opposite the substrate 12, and an N-doped junction gate field-effect transistor (JFET) region 18 between each one of the junction implants 16. Each one of the junction implants 16 is formed by an ion implantation process, and includes a P-doped deep well region 20, a P-doped base region 22, and an N-doped source region 24. Each deep well region 20 extends from a corner of the drift layer 14 opposite the substrate 12 downwards towards the substrate 12 and inwards towards the center of the drift layer 14. The deep well region 20 may be formed uniformly or include one or more protruding regions. Each base region 22 is formed vertically from the surface of the drift layer 14 opposite the substrate 12 down towards the substrate 12 along a portion of the inner edge of each one of the deep well regions 20. Each source region 24 is formed in a shallow portion on the surface of the drift layer 14 opposite the substrate 12, and extends laterally to overlap a portion of the deep well region 20 and the base region 22, without extending over either. The JFET region 18 defines a channel width 26 between each one of the junction implants 16.

A gate oxide layer 28 is positioned on the surface of the drift layer 14 opposite the substrate 12, and extends laterally between a portion of the surface of each source region 24, such that the gate oxide layer 28 partially overlaps and runs between the surface of each source region 24 in the junction implants 16. A gate contact 30 is positioned on top of the gate oxide layer 28. Two source contacts 32 are each positioned on the surface of the drift layer 14 opposite the substrate 12 such that each one of the source contacts 32 partially overlaps both the source region 24 and the deep well region 20 of one of the junction implants 16, respectively, and does not contact the gate oxide layer 28 or the gate contact 30. A drain contact 34 is located on the surface of the substrate 12 opposite the drift layer 14.

As will be appreciated by those of ordinary skill in the art, the structure of the conventional power MOSFET device 10 includes a built-in anti-parallel body diode between the source contacts 32 and the drain contact 34 formed by the junction between each one of the deep well regions 20 and the drift layer 14. The built-in anti-parallel body diode may negatively impact the performance of the conventional power MOSFET device 10 by impeding the switching speed of the device, as will be discussed in further detail below.

In operation, when a biasing voltage below the threshold voltage of the conventional power MOSFET device 10 is applied to the gate contact 30 and the junction between each deep well region 20 and the drift layer 14 is reverse biased, the conventional power MOSFET device 10 is placed in an OFF state. In the OFF state of the conventional power MOSFET device 10, any voltage between the source contacts 32 and the drain contact 34 is supported by the drift layer 14. Due to the vertical structure of the conventional power MOSFET device 10, large voltages may be placed between the source contacts 32 and the drain contact 34 without damaging the device.

FIG. 2A shows operation of the conventional power MOSFET device 10 when the device is in an ON state (first quadrant) of operation. When a positive voltage is applied to the drain contact 34 of the conventional power MOSFET device 10 relative to the source contacts 32 and the gate voltage increases above the threshold voltage of the device, an inversion layer channel 36 is formed at the surface of the drift layer 14 underneath the gate contact 30, thereby placing the conventional power MOSFET device 10 in an ON state. In the ON state of the conventional power MOSFET device 10, current (shown by the shaded region in FIG. 2A) is allowed to flow from the drain contact 34 to each one of the source contacts 32 in the device. An electric field presented by junctions formed between the deep well region 20, the base region 22, and the drift layer 14 constricts current flow in the JFET region 18 into a JFET channel 38 having a JFET channel width 40. At a certain spreading distance 42 from the inversion layer channel 36 when the electric field presented by the junction implants 16 is diminished, the flow of current is distributed laterally, or spread out in the drift layer 14, as shown in FIG. 2A. The JFET channel width 40 and the spreading distance 42 determine the internal resistance of the conventional power MOSFET device 10, thereby dictating the performance of the device. A conventional power MOSFET device 10 generally requires a channel width 26 of three microns or wider in order to sustain an adequate JFET channel width 40 and spreading distance 42 for proper operation of the device.

FIG. 2B shows operation of the conventional power MOSFET device 10 when the device is operating in the third quadrant. When a voltage below the threshold voltage of the device is applied to the gate contact 28 of the conventional power MOSFET device 10 and a positive voltage is applied to the source contacts 32 relative to the drain contact 34 of the device, current will flow from the source contacts 32 through each respective deep well region 26 and into the drift layer 14. In other words, current will flow through each built-in anti-parallel body diode in the conventional power MOSFET device 10.

As discussed above, a built-in anti-parallel body diode is located between the source contacts 32 and the drain contact 34 of the conventional power MOSFET device 10. Specifically, the built-in anti-parallel body diode is formed by the P-N junction between each one of the P-doped deep well regions 26 and the N-doped drift layer 14. The built-in anti-parallel body diode is a relatively slow minority carrier device. Accordingly, once the built-in anti-parallel body diode is activated in a forward bias mode of operation, majority carriers may linger in the device even after a biasing voltage is no longer present at the gate contact 30 of the conventional power MOSFET device 10. The time it takes the minority carriers of the built-in anti-parallel body diode to recombine in their respective regions is known as the reverse recovery time. During the reverse recovery time of the built-in anti-parallel body diode, the lingering minority carriers may prevent the conventional power MOSFET device 10 from entering an OFF state of operation by allowing current to flow from the drain contact 34 to the source contacts 32. The switching speed of the conventional power MOSFET device 10 may therefore be limited by the reverse recovery time of the built-in anti-parallel body diode.

Conventional solutions to the switching speed ceiling imposed by the built-in anti-parallel body diode have focused on placing an external high-speed bypass diode between the source contact and the drain contact of a power MOSFET device. FIG. 3 shows the conventional power MOSFET device 10 connected to an external bypass diode 44. As will be appreciated by those of ordinary skill in the art, the external bypass diode 44 may be chosen to be a junction barrier Schottky (JBS) diode, because of the low forward voltage, low leakage current, and negligible reverse recovery time afforded by such a device. The external bypass diode includes an anode 46, a cathode 48, a drift layer 50, and one or more junction barrier regions 52. The anode 46 of the external bypass diode 44 is coupled to the source contacts 32 of the conventional power MOSFET device 10. The cathode 48 of the external bypass diode 44 is coupled to the drain contact 34 of the conventional power MOSFET device 10. The anode 46 and the cathode 48 are separated from one another by the drift layer 50. The junction barrier regions 52 are located on the surface of the drift layer 50 in contact with the anode 46, and are laterally separated from one another.

As will be appreciated by those of ordinary skill in the art, the JBS diode combines the desirable low forward voltage of a Schottky diode with the low reverse leakage current of a traditional P-N junction diode. In operation, when a bias voltage below the threshold voltage of the conventional power MOSFET device 10 is applied to the gate contact 30 of the device and the junction between each deep well region 20 and the drift layer 14 is reverse biased, the conventional power MOSFET device 10 is placed in an OFF state and the external bypass diode 44 is placed in a reverse bias mode of operation. In the reverse bias mode of operation of the external bypass diode 44, each one of the P-N junctions formed between the drift layer 50 and the junction barrier regions 52 of the external bypass diode 44 is also reverse biased. Each reverse biased junction generates an electric field that effectively expands to occupy the space between each one of the junction barrier regions 52. The resulting depletion region pinches off any reverse leakage current present in the device.

FIG. 4A shows operation of the conventional power MOSFET device 10 including the external bypass diode 44 when the conventional power MOSFET device 10 is in an ON state (first quadrant) of operation. When a positive voltage is applied to the drain contact 34 of the conventional power MOSFET device 10 relative to the source contacts 32 and the gate voltage increases above the threshold voltage, an inversion layer channel 36 is formed at the surface of the drift layer 14 underneath the gate contact 30, thereby placing the conventional power MOSFET device 10 in an ON state (first quadrant) of operation and placing the external bypass diode 44 in a reverse bias mode of operation. In the ON state (first quadrant) of operation of the conventional power MOSFET device 10, current flows in a substantially similar manner to that shown in FIG. 2A. Additionally, because the external bypass diode 44 is reverse biased, current does not flow through the device.

FIG. 4B shows operation of the conventional power MOSFET device 10 including the external bypass diode 44 when the conventional power MOSFET device 10 is operating in the third quadrant, and the external bypass diode 44 is operating in a forward bias mode of operation. When a bias voltage below the threshold voltage of the conventional power MOSFET 10 is applied to the gate contact 30, and a positive voltage is applied to the source contacts 32 relative to the drain contact 34, the conventional power MOSFET 10 begins to operate in the third quadrant, and the external bypass diode 44 is placed in a forward bias mode of operation. In the forward bias mode of operation of the external bypass diode 44, current (shown by the shaded region in FIG. 4) will flow from the anode 46 through one or more channels 54 in the drift layer 50, each one of the channels 54 having a channel width 56 determined by an electric field generated between each one of the junction barrier regions 52 and the drift layer 50. At a certain spreading distance 58 from the anode 46 of the external bypass diode 44, the electric field presented by the junction between each one of the junction barrier regions 52 and the drift layer 50 becomes less pronounced, and the current spreads out laterally to fill the drift layer 50. Finally, the current is delivered to the cathode 48 of the external bypass diode 44. Although the external bypass diode 44 creates a low impedance path for current flow between the source contacts 32 and the drain contact 34, a small amount of current may still flow through the conventional power MOSFET device 10, as shown in FIG. 4B.

By creating a high-speed, low-impedance path for current flow around the built-in anti-parallel body diode, only a small number of minority carriers accumulate in the built-in anti-parallel body diode when the conventional power MOSFET device 10 is operated in the third quadrant. By reducing the number of minority carriers accumulated in the device, the reverse recovery time of the built-in anti-parallel body diode can be substantially reduced. Accordingly, the switching time of the conventional power MOSFET device 10 is no longer limited by the reverse recovery time of the built-in anti-parallel body diode.

Although effective at lifting the switching speed ceiling imposed by the built-in anti-parallel body diode of the conventional power MOSFET device 10, the external bypass diode 44 may increase the ON state resistance as well as the parasitic capacitance of the conventional power MOSFET device 10, thereby degrading the performance of the device. Additionally, the external bypass diode 44 will consume valuable real estate in a device in which the conventional power MOSFET device 10 is integrated.

Specifically, the external bypass diode 44 is a conventional JBS diode, which may increase the ON state resistance of the conventional power MOSFET device 10 due to one or more design constraints inherent to conventional JBS diodes. Conventional JBS diodes are typically designed in order to mitigate the presence of an electric field between each one of the junction barrier regions 52, which may be especially high in Silicon Carbide (SiC) JBS diodes. As will be appreciated by those of ordinary skill in the art, a large electric field presented between each one of the junction barrier regions 52 may result in damage to the crystalline structure of the drift layer 50, thereby degrading the performance of the external bypass diode 44 or causing the device to fail altogether. One way to reduce the electric field generated between each one of the junction implants is to reduce the distance between the junction implants 52 (W_{SCH}). However, such a reduction in the electric field comes at the expense of the ON resistance of the external bypass diode 44, which increases as the distance between the junction implants 52 (W_{SCH}) decreases. Accordingly, a balance must be struck between the two parameters, resulting in sub-optimal performance of the external bypass diode 44. Generally, the distance between the junction implants 52 (W_{SCH}) in a conventional JBS diode is larger than 3 μm in order to maintain desirable ON resistance characteristics of the device. Accordingly, there is a need for a JBS diode with a reduced electric field and improved ON resistance, and a further need for a power MOSFET device with a high switching speed, a low ON state resistance, a low parasitic capacitance, and a compact form factor.

### SUMMARY

The present disclosure relates to junction barrier Schottky (JBS) diodes and methods of manufacturing the same. According to one embodiment, a semiconductor device includes a substrate, a drift layer over the substrate, a spreading layer over the drift layer, and a pair of junction implants in a surface of the spreading layer opposite the drift layer. An anode covers the surface of the spreading layer opposite the drift layer, and a cathode covers a surface of the substrate opposite the drift layer. By including the spreading layer, a better balance can be struck between the on state resistance of the semiconductor device and the peak electric field in the device, thereby improving the performance thereof.

According to one embodiment, a method of manufacturing a semiconductor device includes growing a drift layer on a substrate, growing a spreading layer over the drift layer, implanting a pair of junction barrier regions in a surface of the spreading layer opposite the drift layer, providing an anode contact over the surface of the spreading layer opposite the drift layer, and providing a cathode contact over a surface of the substrate opposite the drift layer. By providing the spreading layer, a better balance can be struck between the on state resistance of the semiconductor device and the peak electric field in the device, thereby improving the performance thereof.

According to one embodiment, a JBS diode includes a substrate, a drift layer over the substrate, a spreading layer over the drift layer, and a pair of junction barrier regions in a surface of the spreading layer opposite the drift layer. Including the spreading layer reduces the on-state resistance of the JBS diode and further allows the leakage current of the JBS diode to remain less than 150 nA/cm², thereby improving the performance of the JBS diode.

According to one embodiment, a semiconductor device comprises a substrate, a drift layer over the substrate, and a spreading layer over the drift layer. The spreading layer includes a pair of trenches, which extend from a surface of the spreading layer opposite the drift layer down into the spreading layer towards the drift layer. A pair of junction implants is located in each one of the trenches. An anode contact is located over the surface of the spreading layer opposite the drift layer and in each one of the trenches. A cathode contact is located over a surface of the substrate opposite the drift layer. The spreading layer allows a better balance to be struck between the on state resistance of the semiconductor device and the peak electric field in the device, thereby improving the performance thereof.

According to one embodiment, a method of manufacturing a semiconductor device includes growing a drift layer on a substrate, growing a spreading layer over the drift layer, etching a pair of trenches in the surface of the spreading layer opposite the drift layer, which extend into the spreading layer towards the drift layer, implanting a pair of junction implants in the trenches, providing an anode contact over the surface of the spreading layer opposite the drift layer and in the trenches, and providing a cathode contact over a surface of the substrate opposite the drift layer. By providing the spreading layer, a better balance can be struck between the on state resistance of the semiconductor device and the peak electric field in the device, thereby improving the performance thereof.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 shows a schematic representation of a conventional power metal-oxide-semiconductor field-effect transistor (MOSFET) device.

FIG. 2A shows details of the operation of the conventional power MOSFET device shown in FIG. 1 when the device is in an ON state of operation.

FIG. 2B shows details of the operation of the conventional power MOSFET device shown in FIG. 1 when the device is operated in the third quadrant.

FIG. 3 shows a schematic representation of the conventional power MOSFET device shown in FIG. 1 attached to an external bypass diode.

FIG. 4A shows details of the operation of the conventional power MOSFET device and attached external bypass diode when the device is in an ON state of operation.

FIG. 4B shows details of the operation of the conventional power MOSFET device and attached external bypass diode when the conventional power MOSFET is operated in the third quadrant.

FIG. 5 shows a vertical field-effect transistor (FET) device and integrated bypass diode according to one embodiment of the present disclosure.

FIG. 6A shows details of the operation of the vertical FET device and integrated bypass diode according to one embodiment of the present disclosure.

FIG. 6B shows details of the operation of the vertical FET device and integrated bypass diode according to one embodiment of the present disclosure.

FIG. 7 shows a schematic representation of a vertical FET device and integrated bypass diode according to an additional embodiment of the present disclosure.

FIG. 8 shows a schematic representation of a dual vertical FET device and integrated bypass diode according to one embodiment of the present disclosure.

FIG. 9 shows a schematic representation of a trench vertical FET device and integrated bypass diode according to one embodiment of the present disclosure.

FIG. 10 shows a schematic representation of the trench vertical FET and integrated bypass diode shown in FIG. 9 according to an additional embodiment of the present disclosure.

FIG. 11 shows a schematic representation of the trench vertical FET and integrated bypass diode shown in FIG. 9 according to an additional embodiment of the present disclosure.

FIG. 12 shows a process for manufacturing the vertical FET device and integrated bypass diode shown in FIG. 5 according to one embodiment of the present disclosure.

FIGS. 13-20 illustrate the process described in FIG. 12 for manufacturing the vertical FET device and integrated bypass diode.

FIG. 21 shows a junction barrier Schottky (JBS) diode according to one embodiment of the present disclosure.

FIG. 22 shows a process for manufacturing the JBS diode shown in FIG. 21 according to one embodiment of the present disclosure.

FIGS. 23A-23D illustrate the process described in FIG. 22 for manufacturing the JBS diode.

FIG. 24 shows a JBS diode according to an additional embodiment of the present disclosure.

FIG. 25 shows a process for manufacturing the JBS diode shown in FIG. 24 according to one embodiment of the present disclosure.

FIGS. 26A-26E illustrate the process described in FIG. 25 for manufacturing the JBS diode.

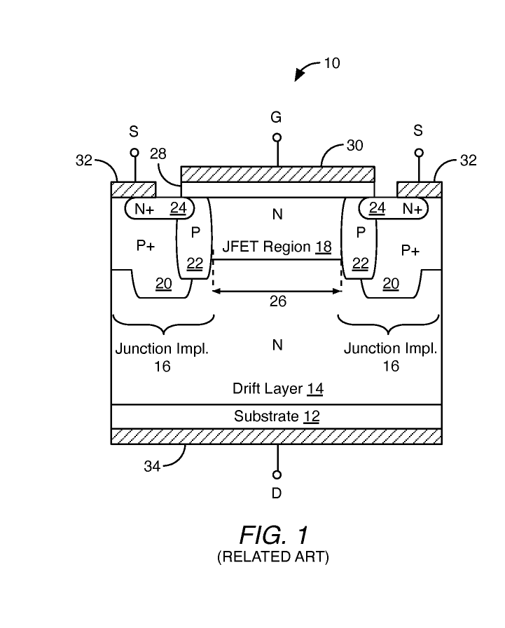

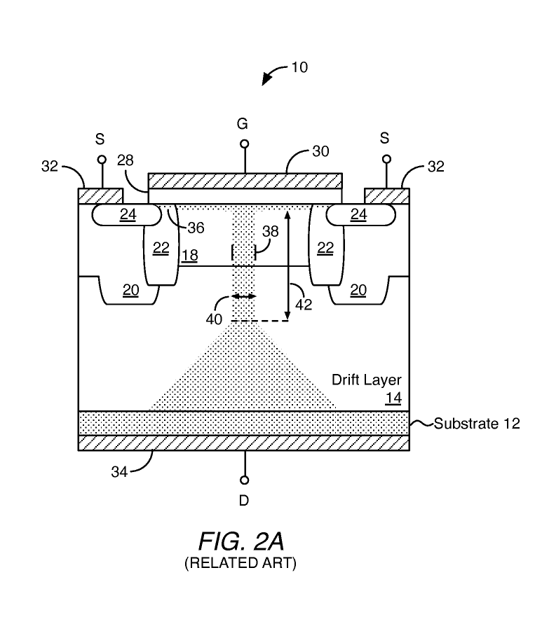

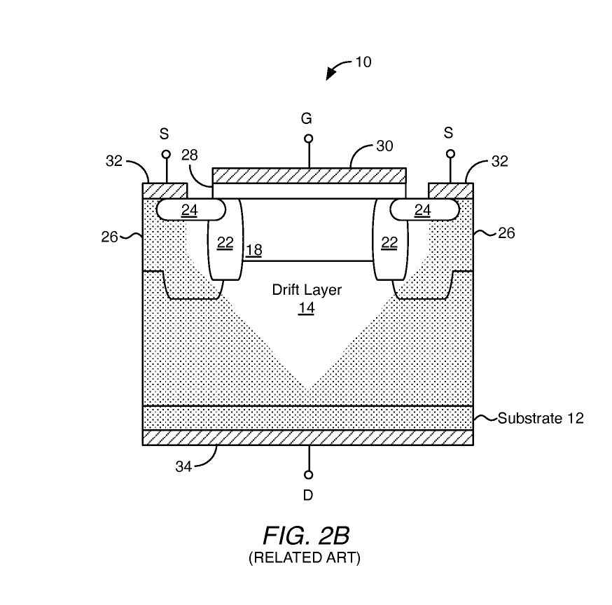

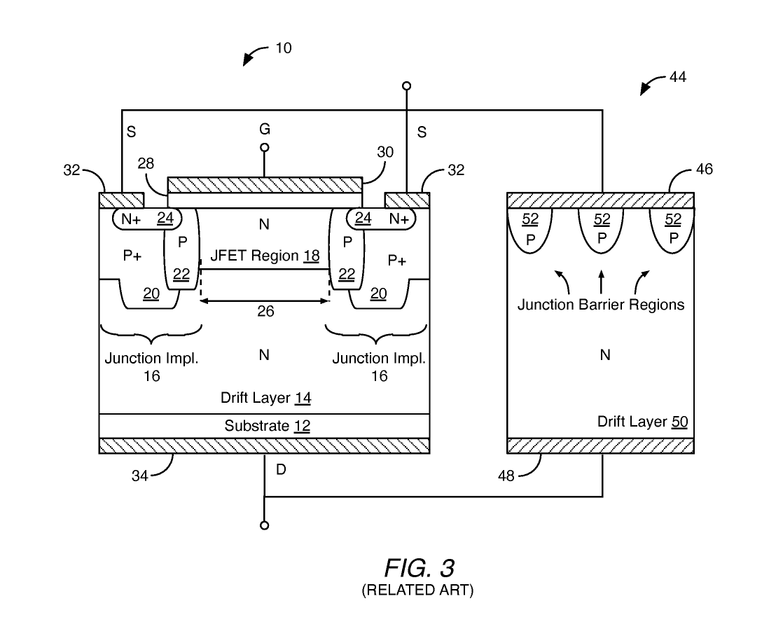

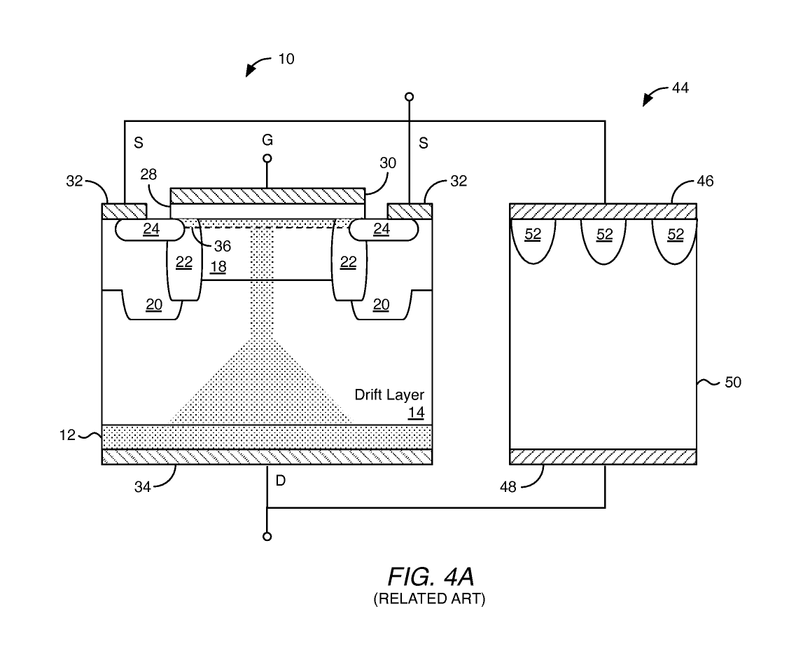

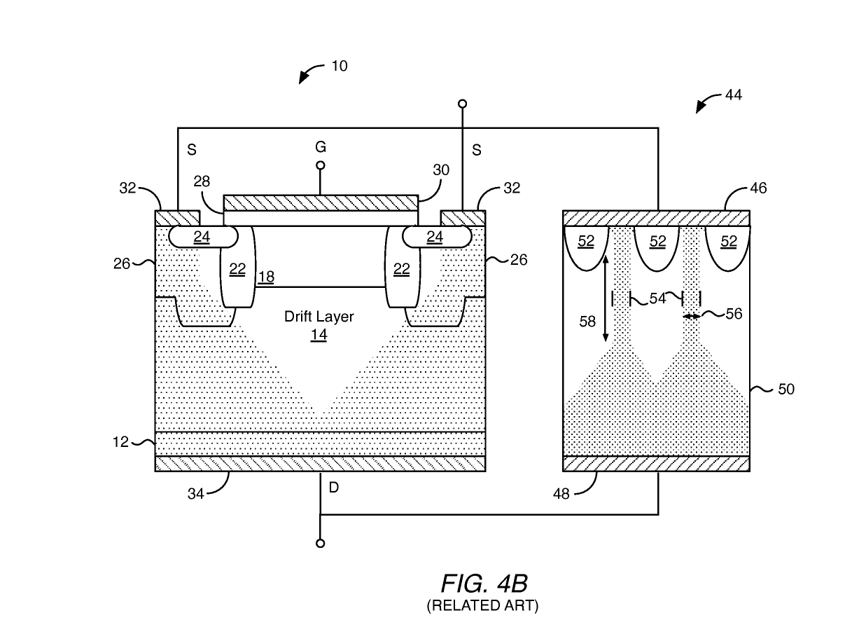

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

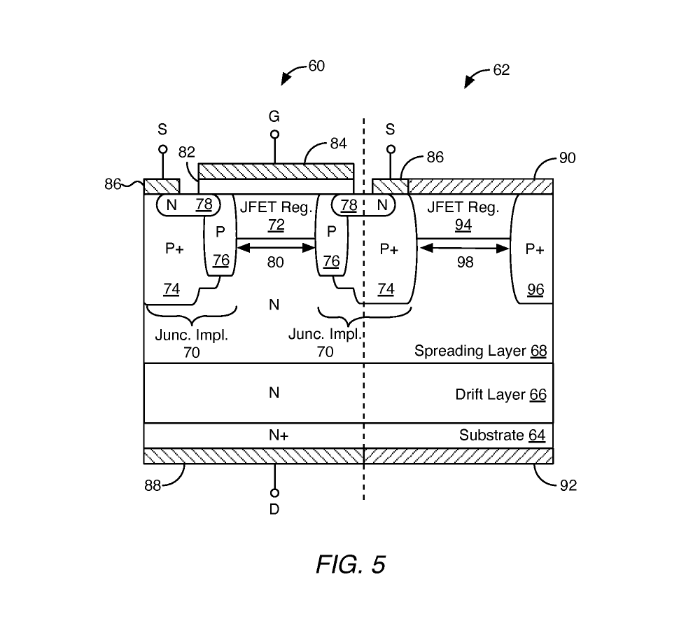

Turning now to FIG. 5, a vertical field-effect transistor (FET) device 60 is shown including a monolithically integrated bypass diode 62. The vertical FET device 60 includes a substrate 64, a drift layer 66 formed over the substrate 64, a spreading layer 68 formed over the drift layer 66, one or more junction implants 70 in the surface of the spreading layer 68 opposite the drift layer 66, and a junction gate field-effect transistor (JFET) region 72 between each one of the junction implants 70. Each one of the junction implants 70 may be formed by an ion implantation process, and includes a deep well region 74, a base region 76, and a source region 78. Each deep well region 74 extends from a corner of the spreading layer 68 opposite the drift layer 66 downwards towards the drift layer 66 and inwards towards the center of the spreading layer 68. The deep well region 74 may be formed uniformly or include one or more protruding regions. Each base region 76 is formed vertically from the surface of the spreading layer 68 opposite the drift layer 66 down towards the drift layer 66 along a portion of the inner edge of each one of the deep well regions 74. Each source region 78 is formed in a shallow portion on the surface of the spreading layer 68 opposite the drift layer 66, and extends laterally to overlap a portion of the deep well region 74 and the base region 76, without extending over either. The JFET region 72 defines a channel width 80 between each one of the junction implants 70.

A gate oxide layer 82 is positioned on the surface of the spreading layer 68 opposite the drift layer 66, and extends laterally between a portion of the surface of each source region 78, such that the gate oxide layer 82 partially overlaps and runs between the surface of each source region 78 in the junction implants 70. A gate contact 84 is positioned on top of the gate oxide layer 82. Two source contacts 86 are each positioned on the surface of the spreading layer 68 opposite the drift layer 66 such that each one of the source contacts 86 partially overlaps both the source region 78 and the deep well region 74 of each one of the junction implants 70, respectively, and does not contact the gate oxide layer 82 or the gate contact 84. A drain contact 88 is located on the surface of the substrate 64 opposite the drift layer 66.

The integrated bypass diode 62 is formed adjacent to the vertical FET device 60 on the same semiconductor die. The integrated bypass diode 62 includes the substrate 64, the drift layer 66, the spreading layer 68, one of the deep well regions 74, an anode 90, a cathode 92, a JFET region 94, and a deep junction barrier region 96. The anode 90 is joined with one of the source contacts 86 of the vertical FET device 60 on a surface of the spreading layer 68 opposite the drift layer 66. The cathode 92 is joined with the drain contact 88 of the vertical FET device 60 on a surface of the substrate 64 opposite the drift layer 66. The deep junction barrier region 96 is separated from the deep well region 74 of the vertical FET device 60 by the JFET region 94. The JFET region 94 defines a channel width 98 between the shared deep well region 74 and the deep junction barrier region 96.

The shared deep well region 74 effectively functions as both a deep well region in the vertical FET device 60 and a junction barrier region in the integrated bypass diode 62. By sharing one of the deep well regions 74 between the vertical FET device 60 and the integrated bypass diode 62, the built-in anti-parallel body diode formed by the junction between the shared deep well region 74 and the spreading layer 68 is effectively re-used to form one of the junction barrier regions of the integrated bypass diode 62.

As will be appreciated by those of ordinary skill in the art, in certain applications the integrated bypass diode 62 may be connected in opposite polarity, wherein the anode 90 is coupled to the drain contact 88 of the vertical FET device 60 and the cathode 92 is coupled to the source of the vertical FET device 60. This may occur, for example, when the vertical FET device 60 is a P-MOSFET device.

In operation, when a biasing voltage below the threshold voltage of the vertical FET device 60 is applied to the gate contact 84 and the junction between each deep well region 74 and the drift layer 66, as well as the deep junction barrier region 96 and the drift layer 66, is reverse biased, the vertical FET device 60 is placed in an OFF state of operation, and the integrated bypass diode 62 is placed in a reverse bias state of operation. Each reverse-biased junction generates an electric field that effectively expands to occupy the space between each one of the junction implants 70 and the deep junction barrier region 96. Accordingly, little to no leakage current is passed through the vertical FET device 60 or the integrated bypass diode 62. In the OFF state of operation of the vertical FET device 60, any voltage between the source contacts 86 and the drain contact 88 is supported by the drift layer 66 and the spreading layer 68. Due to the vertical structure of the vertical FET device 60, large voltages may be placed between the source contacts 86 and the drain contact 88 without damaging the device.

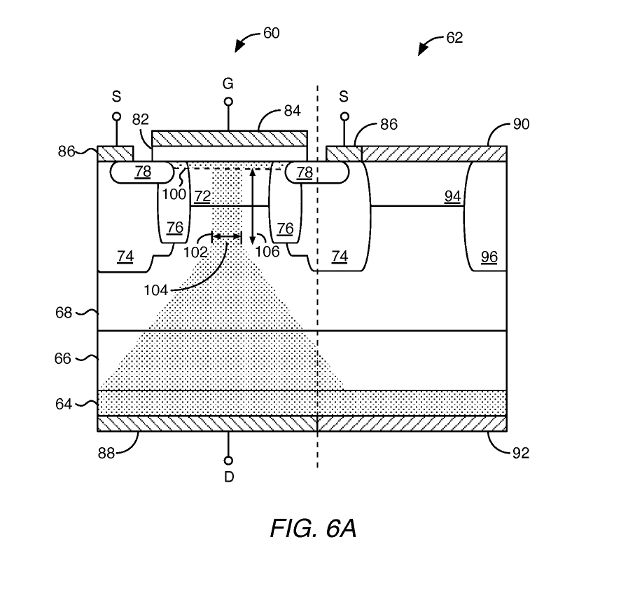

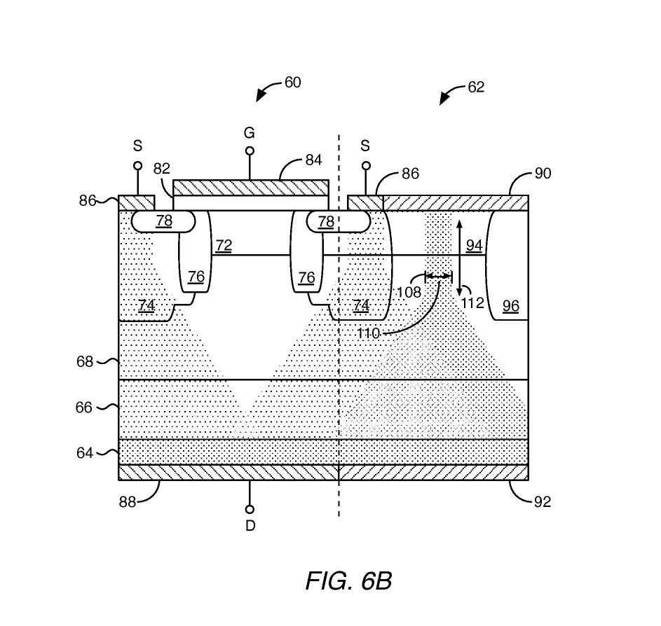

FIG. 6A shows operation of the vertical FET device 60 and integrated bypass diode 62 when the vertical FET device 60 is in an ON state (first quadrant) of operation and the integrated bypass diode 62 is in a reverse bias mode of operation. When a positive voltage is applied to the drain contact 88 of the vertical FET device 60 relative to the source contact 86 and the gate voltage increases above the threshold voltage of the device, an inversion layer channel 100 is formed at the surface of the spreading layer 68 underneath the gate contact 84, thereby placing the vertical FET device 60 in an ON state of operation and placing the integrated bypass diode 62 in a reverse bias mode of operation. In the ON state of operation of the vertical FET device 60, current (shown by the shaded region in FIG. 6) is allowed to flow from the drain contact 88 to the source contacts 86 of the device. An electric field presented by the junctions formed between the deep well region 74, the base region 76, and the spreading layer 68 constricts current flow in the JFET region 72 into a JFET channel 102 having a JFET channel width 104. At a certain spreading distance 106 from the inversion layer channel 100 when the electric field presented by the junction implants 70 is diminished, the flow of current is distributed laterally, or spread out, in the spreading layer 68, as shown in FIG. 6. Because the integrated bypass diode 62 is reverse biased, current does not flow through the device.

FIG. 6B shows operation of the vertical FET device 60 and integrated bypass diode 62 when the vertical FET device 60 is operated in the third quadrant. When a bias voltage below the threshold voltage of the device is applied to the gate contact 84 of the vertical FET device 60 and a positive voltage is applied to the source contacts 86 relative to the drain contact 88, the vertical FET device 60 begins to operate in the third quadrant, and the integrated bypass diode 62 is placed in a forward bias mode of operation. In the third quadrant of operation, current flows from the source contacts 86 of the vertical FET device 60 through the deep well regions 74 and into the spreading layer 68, where it then travels through the drift layer 66 and the substrate 64 to the drain contact 88. Further, current flows from the anode 90 of the integrated bypass diode 62 into the spreading layer 68, where it then travels through the drift layer 66 and the substrate 64 to the drain contact 88.

Due to the low impedance path provided by the integrated bypass diode 62, the majority of the current flow through the vertical FET device 60 flows through the anode 90 of the integrated bypass diode 62 into the JFET region 94 of the device. In the JFET region 94, electromagnetic forces presented by the deep well region 74 and the deep junction barrier region 96 constrict current flow into a JFET channel 108 having a JFET channel width 110. At a certain spreading distance 112 from the anode 90 of the integrated bypass diode 62 when the electric field presented by the deep well region 74 and the deep junction barrier region 96 is diminished, the flow of current is distributed laterally, or spread out in the drift layer 66.

The spreading layer 68 of the integrated bypass diode 62 and vertical FET device 60 is doped in such a way to decrease resistance in the current path of each device. Accordingly, the JFET channel width 104 of the vertical FET device 60, the JFET channel width 110 of the integrated bypass diode 62, the spreading distance 106 of the vertical FET device 60, and the spreading distance 112 of the integrated bypass diode 62 may be decreased without negatively affecting the performance of either device. In fact, the use of the spreading layer 68 significantly decreases the ON resistance of both the vertical FET device 60 and the integrated bypass diode 62. A decreased ON resistance leads to a higher efficiency of the vertical FET device 60 and integrated bypass diode 62.

By monolithically integrating the vertical FET device 60 and the integrated bypass diode 62, each one of the devices is able to share the spreading layer 68, the drift layer 66, and the substrate 64. By sharing the spreading layer 68, the drift layer 66, and the substrate 64, the overall area available for current flow in the device is increased, thereby further decreasing the ON resistance of the integrated bypass diode 62 and the vertical FET device 60. Additionally, sharing the spreading layer 68, the drift layer 66, and the substrate 64 provides a greater area for heat dissipation for the integrated bypass diode 62 and the vertical FET device 60, which in turn allows the device to handle more current without risk of damage. Finally, by sharing one of the deep well regions 74 of the vertical FET device 60 with the integrated bypass diode 62, both of the devices can share a common edge termination. Since edge termination can consume a large fraction of the area in semiconductor devices, combining the integrated bypass diode 62 and the vertical FET device 60 with the shared deep well region 74 allows the area of at least one edge termination to be saved.

The advantages of combining the integrated bypass diode 62 and the vertical FET device 60 using a shared deep well region 74 allow for a better trade-off between the ON state forward drop of the integrated bypass diode 62 and the peak electric field in the Schottky interface between the anode 90 and the spreading layer 68. The reduction of the peak electric field in the Schottky interface between the anode 90 and the spreading layer 68 may allow the integrated bypass diode 62 to use a low barrier height Schottky metal for the anode 90, such as Tantalum.

The vertical FET device 60 may be, for example, a metal-oxide-silicon field-effect transistor (MOSFET) device made of silicon carbide (SiC). Those of ordinary skill in the art will appreciate that the concepts of the present disclosure may be applied to any materials system. The substrate 64 of the vertical FET device 60 may be about 180-350 microns thick. The drift layer 66 may be about 3.5-250 microns thick, depending upon the voltage rating of the vertical FET device 60. The spreading layer 68 may be about 1.0-2.5 microns thick. Each one of the junction barrier regions 52 may be about 1.0-2.0 microns thick. The JFET region 72 may be about 0.75-1.0 microns thick. The deep junction barrier region 96 may be about 1.0-2.0 microns thick.

According to one embodiment, the spreading layer 68 is an N-doped layer with a doping concentration about 1×10¹⁶ cm⁻³ to 2×10¹⁷ cm⁻³. The spreading layer 68 may be graded, such that the portion of the spreading layer 68 closest to the drift layer 66 has a doping concentration about 1×10¹⁶ cm⁻³ that is graduated as the spreading layer 68 extends upward to a doping concentration of about 2×10¹⁷ cm⁻³. According to an additional embodiment, the spreading layer 68 may comprise multiple layers. The layer of the spreading layer 68 closest to the drift layer may have a doping concentration of about 1×10¹⁶ cm⁻³. The doping concentration of each additional layer in the spreading layer 68 may decrease in proportion to the distance of the layer from the JFET region 72 of the vertical FET device 60. The portion of the spreading layer 68 farthest from the drift layer 66 may have a doping concentration about 2×10¹⁷ cm⁻³.

The JFET region 72 may be an N-doped layer with a doping concentration from about 1×10¹⁶ cm⁻³ to 1×10¹⁷ cm⁻³. The drift layer 66 may be an N-doped layer with a doping concentration about 3×10¹⁴ cm⁻³ to 1.5×10¹⁶ cm⁻³. The deep well region 74 may be a heavily P-doped region with a doping concentration about 5×10¹⁷ cm⁻³ to 1×10²⁰ cm⁻³. The base region 76 may be a P-doped region with a doping concentration from about 5×10¹⁶ cm⁻³ to 1×10¹⁹ cm⁻³. The source region 78 may be an N-doped region with a doping concentration from about 1×10¹⁹ cm⁻³ to 1×10²¹ cm⁻³. The deep junction barrier region 96 may be a heavily P-doped region with a doping concentration about 5×10¹⁷ cm⁻³ to 1×10²⁰ cm⁻³. The N doping agent may be nitrogen, phosphorous, or any other suitable element or combination thereof, as will be appreciated by those of ordinary skill in the art. The P-doping agent may be aluminum, boron, or any other suitable element or combination thereof, as will be appreciated by those of ordinary skill in the art.

The gate contact 84, the source contacts 86, and the drain contact 88 may be comprised of multiple layers. For example, each one of the contacts may include a first layer of nickel or nickel-aluminum, a second layer of titanium over the first layer, a third layer of titanium-nickel over the second layer, and a fourth layer of aluminum over the third layer. The anode 90 and the cathode 92 of the integrated bypass diode 62 may comprise titanium. Those or ordinary skill in the art will appreciate that the gate contact 84, the source contacts 86, and the drain contact 88 of the vertical FET device 60 as well as the anode 90 and the cathode 92 of the integrated bypass diode 62 may be comprised of any suitable material without departing from the principles of the present disclosure.

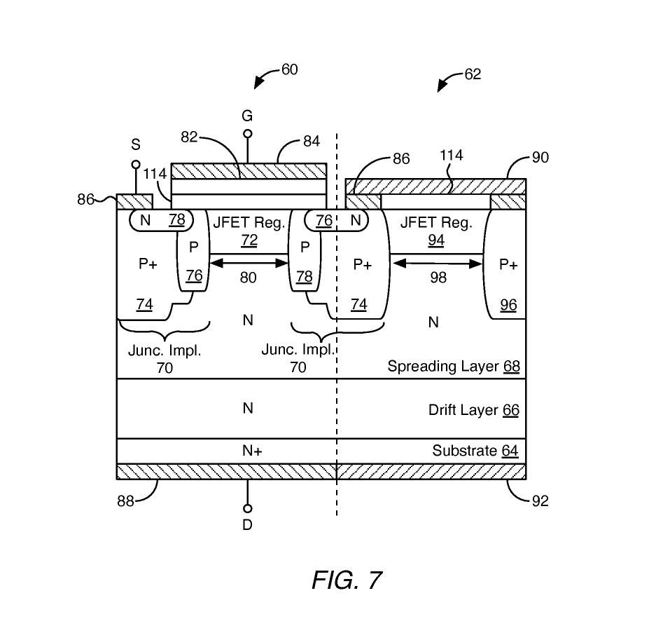

FIG. 7 shows the vertical FET device 60 including the integrated bypass diode 62 according to an additional embodiment of the present disclosure. The vertical FET device 60 shown in FIG. 7 is substantially similar to that shown in FIG. 5, but further includes a channel re-growth layer 114 between the gate oxide layer 82 of the vertical FET device 60 and the spreading layer 68, and also between the anode 90 of the integrated bypass diode 62 and the spreading layer 68. The channel re-growth layer 114 is provided to lower the threshold voltage of the vertical FET device 60 and the integrated bypass diode 62. Specifically, the deep well regions 74 of the vertical FET device 60 and the deep junction barrier region 96 of the integrated bypass diode 62, due to their high doping levels, may raise the threshold voltage of the vertical FET device 60 and the integrated bypass diode 62 to a level that inhibits optimal performance. Accordingly, the channel re-growth layer 114 may offset the effects of the deep well regions 74 and the deep junction barrier region 96 in order to lower the threshold voltage of the vertical FET device 60 and the integrated bypass diode 62. The channel re-growth layer 114 may be an N-doped region with a doping concentration from about 1×10¹⁵ cm⁻³ to 1×10¹⁷ cm⁻³.

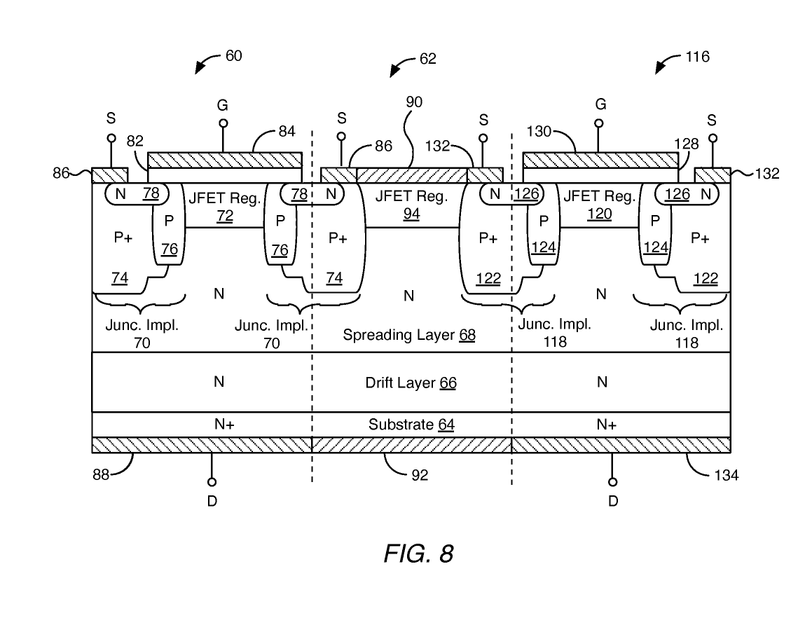

FIG. 8 shows the vertical FET device 60 including the integrated bypass diode 62 according to an additional embodiment of the present disclosure. The vertical FET device 60 shown in FIG. 8 is substantially similar to that shown in FIG. 5, but further includes an additional vertical FET device 116 on the side of the integrated bypass diode 62 opposite the vertical FET device 60. The additional vertical FET device 116 is substantially similar to the vertical FET device 60, and includes the substrate 64, the drift layer 66, the spreading layer 68, a pair of junction implants 118 in the surface of the spreading layer 68, and a JFET region 120 between each one of the junction implants 118. Each one of the junction implants 118 may be formed by an ion implantation process, and includes a deep well region 122, a base region 124, and a source region 126. Each deep well region 122 extends from a corner of the spreading layer 68 opposite the drift layer 66 downwards towards the drift layer 66 and inwards towards the center of the spreading layer 68. The deep well regions 122 may be formed uniformly or include one or more protruding regions. Each base region 124 is formed vertically from the surface of the spreading layer 68 opposite the drift layer 66 downwards towards the drift layer 66 along a portion of the inner edge of each one of the deep well regions 122. Each source region 126 is formed in a shallow portion on the surface of the spreading layer 68 opposite the drift layer 66, and extends laterally to overlap a portion of a respective deep well region 122 and source region 124, without extending over either.

A gate oxide layer 128 is positioned on the surface of the spreading layer 68 opposite the drift layer 66, and extends laterally between a portion of the surface of each source region 126, such that the gate oxide layer 128 partially overlaps and runs between the surface of each source region 126 in the junction implants 118. A gate contact 130 is positioned on top of the gate oxide layer 128. Two source contacts 132 are each positioned on the surface of the spreading layer 68 opposite the drift layer 66 such that each one of the source contacts 132 partially overlaps both the source region 126 and the deep well region 122 of each one of the junction implants 118, respectively, and does not contact the gate oxide layer 128 or the gate contact 130. A drain contact 134 is located on the surface of the substrate 64 opposite the drift layer 66.

As shown in FIG. 8, the integrated bypass diode 62 shares a deep well region with each one of the vertical FET devices. Accordingly, the benefits of the integrated bypass diode 62 are incorporated into each one of the vertical FET devices at a minimal cost. The integrated bypass diode 62 can share at least one edge termination region with both the vertical FET device 60 and the additional vertical FET device 116, thereby saving additional space. Further, current in the device has an even larger spreading layer 68 and drift layer 66 to occupy than that of a single vertical FET device and integrated bypass diode, which may further decrease the ON resistance and thermal efficiency of the device.

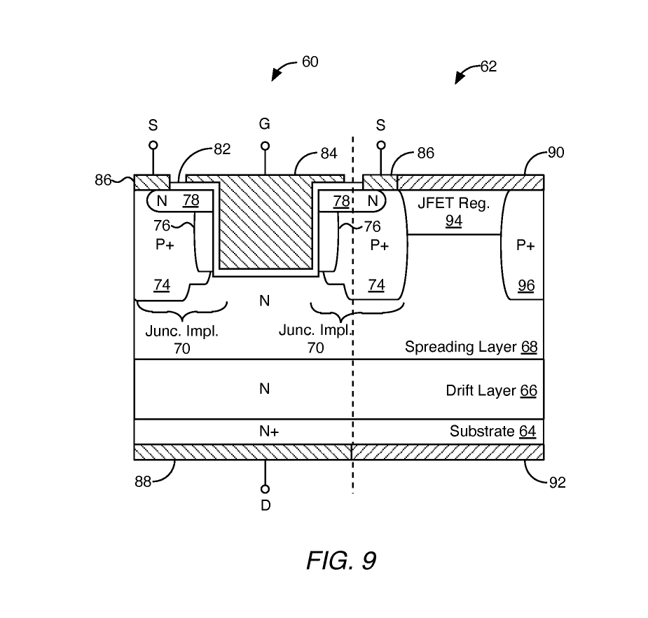

FIG. 9 shows the vertical FET device 60 including the integrated bypass diode 62 according to an additional embodiment of the present disclosure. The vertical FET device 60 shown in FIG. 9 is substantially similar to that shown in FIG. 5, except the vertical FET device 60 shown in FIG. 9 is arranged in a trench configuration. Specifically, the gate oxide layer 82 and the gate contact 84 of the vertical FET device 60 are inset in the spreading layer 68 of the vertical FET device 60 to form a trench transistor device. The gate contact 84 of the vertical FET device 60 may extend 0.75-1.5 microns into the surface of the spreading layer 68 opposite the drift layer 66. The gate oxide layer 82 may form a barrier between the surface of the spreading layer 68, the junction implants 70, and the gate contact 84. The trench-configured vertical FET device 60 shown in FIG. 9 will perform substantially similar to the vertical FET device 60 shown in FIG. 5, but may provide certain performance enhancements, for example, in the ON state resistance of the vertical FET device 60.

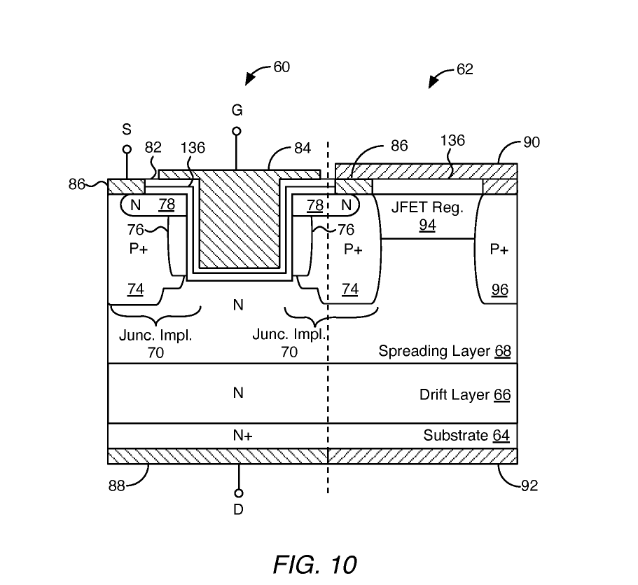

FIG. 10 shows the vertical FET device 60 including the integrated bypass diode 62 according to an additional embodiment of the present disclosure. The vertical FET device 60 shown in FIG. 10 is substantially similar to that shown in FIG. 9, except the vertical FET device 60 further includes a channel re-growth layer 136 between the gate oxide layer 82, the spreading layer 68, and the junction implants 70 of the vertical FET device 60, and also between the anode 90 of the integrated bypass diode 62 and the spreading layer 68. As discussed above, the channel re-growth layer 136 is provided to lower the threshold voltage of the vertical FET device 60 and the integrated bypass diode 62. Specifically, the channel re-growth layer 136 may be provided to offset the effects of the heavily doped deep well regions 74 and deep junction barrier region 96. According to one embodiment, the channel re-growth layer 136 is an N-doped region with a doping concentration from about 1×10¹⁵ cm⁻³ to 1×10¹⁷ cm⁻³.

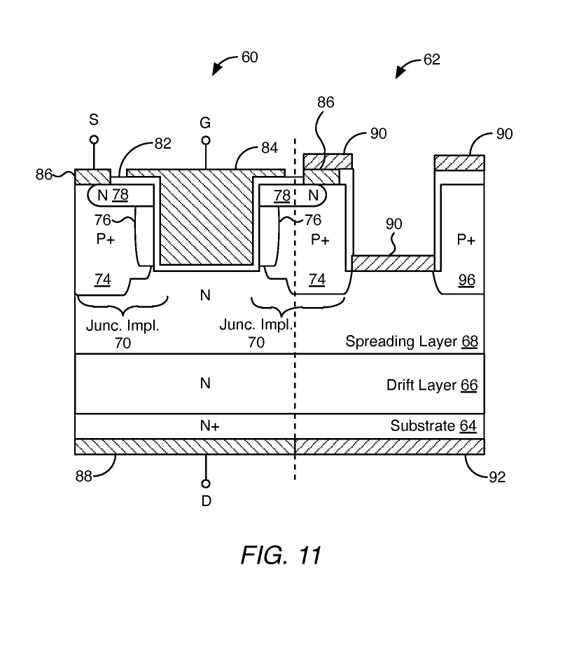

FIG. 11 shows the vertical FET device 60 including the integrated bypass diode 62 according to an additional embodiment of the present disclosure. The vertical FET device 60 shown in FIG. 11 is substantially similar to that shown in FIG. 9, except that the integrated bypass diode 62 coupled to the vertical FET device 60 in FIG. 11 is also arranged in a trench configuration. Specifically, the anode 90 of the integrated bypass diode may be inset in the spreading layer 68 by about 0.75-1.5 microns. An oxide layer may be provided along the lateral portions of the trench in contact with the spreading layer 68 and the junction implants 70. The vertical FET device 60 and integrated bypass diode 62 will perform substantially similar to the devices described above, but may provide certain performance improvements, for example, in the forward bias voltage drop across the integrated bypass diode 62.

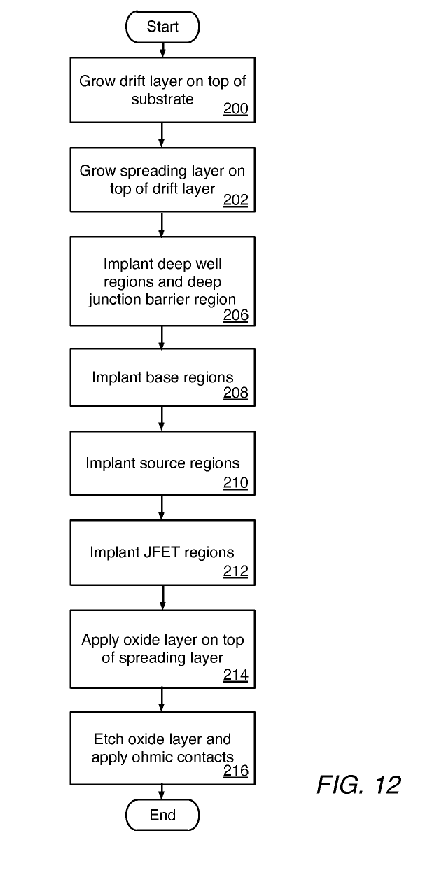

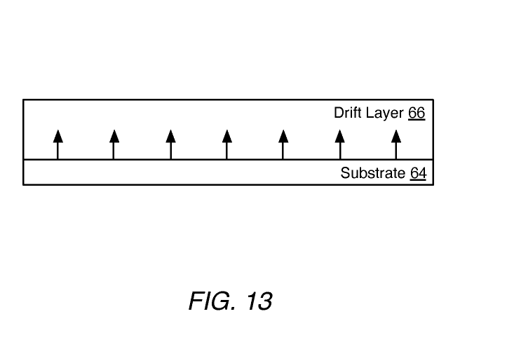

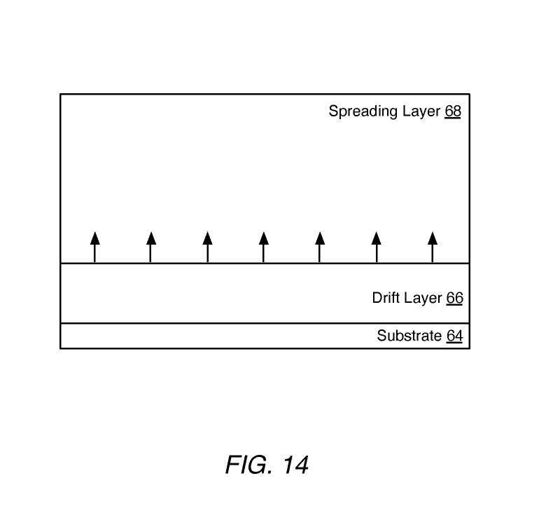

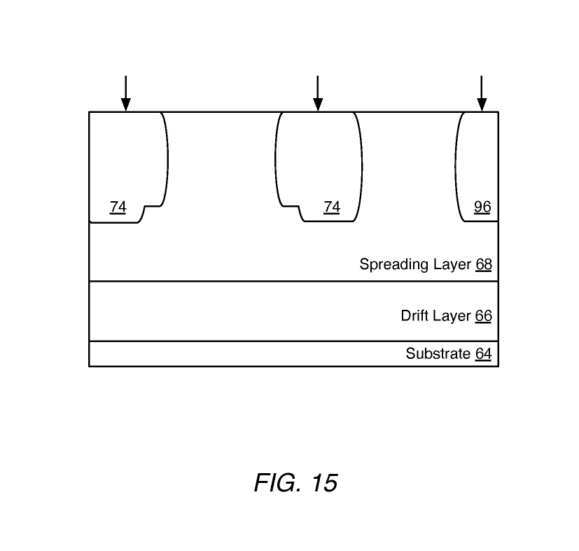

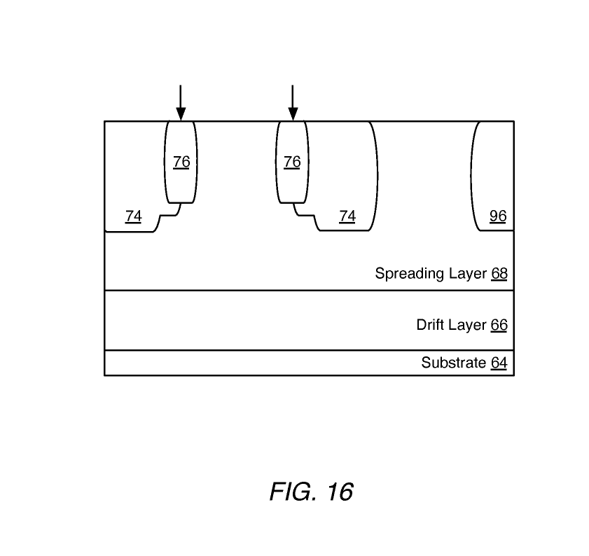

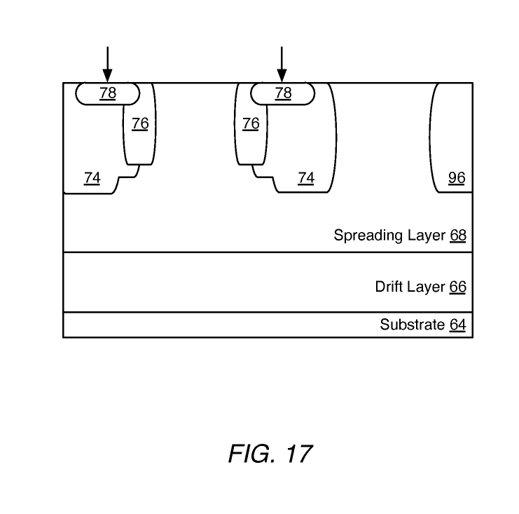

FIG. 12 and the following FIGS. 13-20 illustrate a process for manufacturing the vertical FET device 60 and the integrated bypass diode 62 shown in FIG. 5. First, the drift layer 66 is epitaxially grown on a surface of the substrate 64 (step 200 and FIG. 13). Next, the spreading layer 68 is epitaxially grown on the surface of the drift layer 66 opposite the substrate 64 (step 202 and FIG. 14). The deep well regions 74 and the deep junction barrier region 96 are then implanted (step 206 and FIG. 15). In order to achieve the depth required for the deep well regions 74 and the deep junction barrier region 96, a two-step ion implantation process may be used, wherein boron is used to obtain the necessary depth, while aluminum is used to obtain desirable conduction characteristics of the deep well regions 74 and the deep junction barrier region 96. The base regions 76 are then implanted (step 208 and FIG. 16). Next, the source regions 78 are implanted (step 210 and FIG. 17). The deep well regions 74, the base regions 76, the source regions 78, and the deep junction barrier region 96 may be implanted via an ion implantation process. Those of ordinary skill in the art will realize that the deep well regions 74, the base regions 76, the source regions 78, and the deep junction barrier region 96 may be created by any suitable process without departing from the principles of the present disclosure.

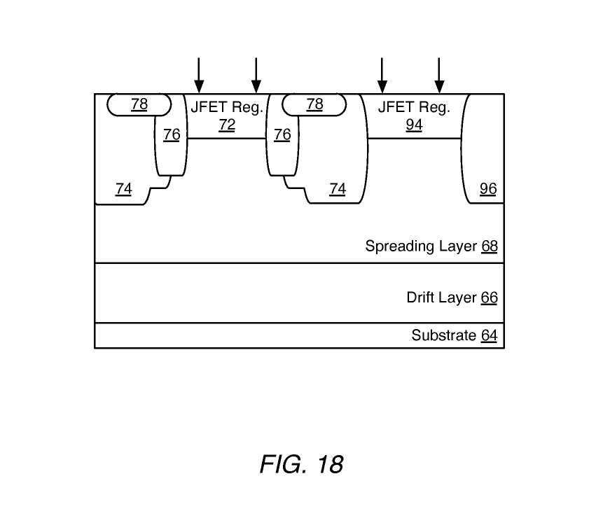

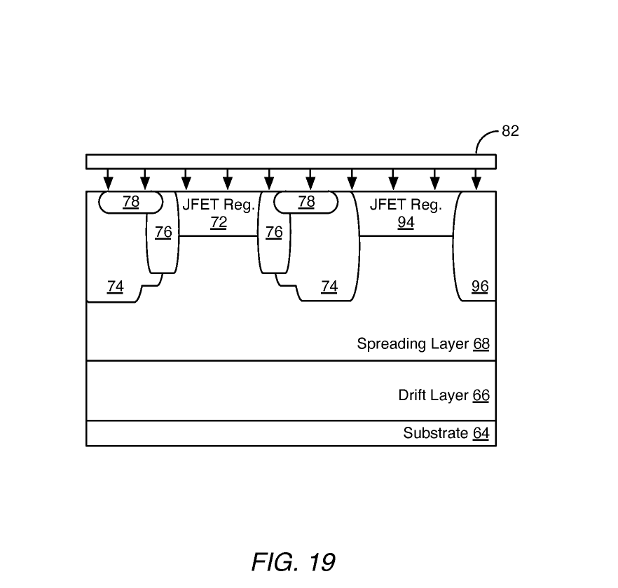

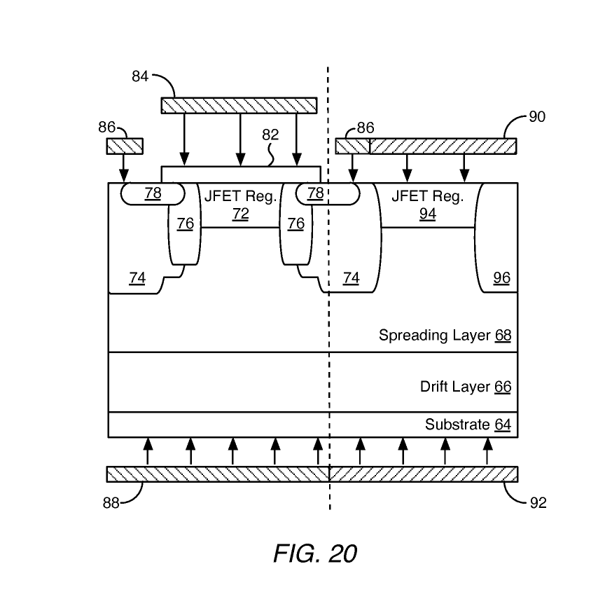

Next, the JFET region 72 of the vertical FET device 60 and the JFET region 94 of the integrated bypass diode 62 are implanted, for example, by an ion implantation process (step 212 and FIG. 18). The JFET region 72 of the vertical FET device 60 and the JFET region 94 of the integrated bypass diode 62 may also be epitaxially grown together as a single layer, and later etched into their individual portions. The gate oxide layer 82 is then applied to the surface of the spreading layer 68 opposite the drift layer 66 (step 214 and FIG. 19). The gate oxide layer 82 is then etched, and the ohmic contacts (gate contact 84, source contacts 86, drain contact 88, anode 90, and cathode 92) are attached to the vertical FET device 60 and the integrated bypass diode 62 (step 216 and FIG. 20). An over-mold layer may be provided over the surface of the spreading layer 68 opposite the drift layer 66 to protect the vertical FET device 60 and integrated bypass diode 62.

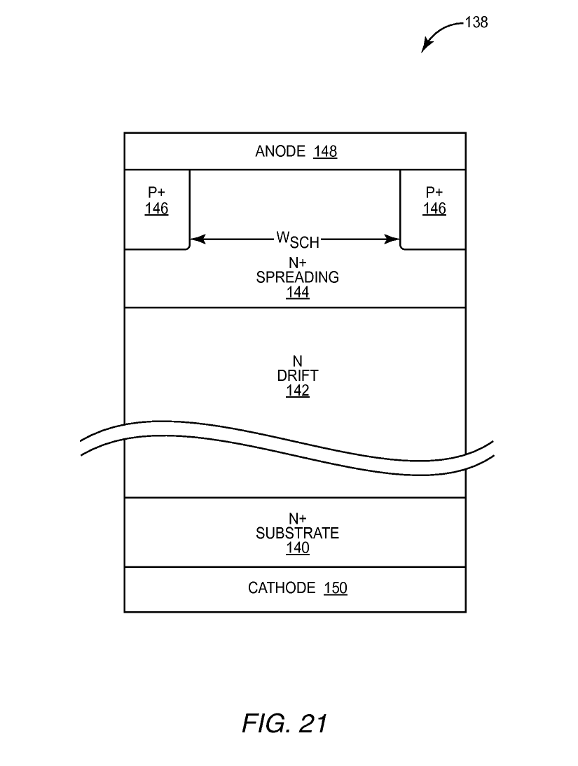

FIG. 21 shows an isolated JBS diode 138 according to one embodiment of the present disclosure. As discussed above, the JBS diode 138 includes a substrate 140, a drift layer 142 over the substrate 140, a spreading layer 144 over the drift layer 142, a pair of junction barrier regions 146 in the surface of the spreading layer 144 opposite the drift layer 142, an anode 148 over the spreading layer 144, and a cathode 150 over the surface of the substrate 140 opposite the drift layer 142. As discussed above, providing the spreading layer 144 significantly reduces the ON resistance of the JBS diode 138, thereby allowing the distance between the junction barrier regions 146 (W_{SCH}), and thus the electric field presented between each one of the junction barrier regions 146, to be reduced as well. As the strength of the electric field is inversely related to the leakage current of the JBS diode 138, the leakage current of the JBS diode 138 is also reduced. In one exemplary embodiment, the ON resistance of the JBS diode 138 may be below 54 mΩ-cm², while the leakage current of the JBS diode 138 may be below 150 nA/cm² at a reverse voltage of 5.5 kV. Generally, the ON resistance of the JBS diode 138 is related to the breakdown voltage of the diode, as shown in Equation (1) below:

R_{ON}=2*10⁻¹¹(V_{BD})^{2.4425} (1)

where R_{ON} is the ON resistance of the JBS diode 138 and V_{BD} is the breakdown voltage of the JBS diode 138. Accordingly, a better trade-off between the ON state forward drop of the JBS diode 138 and the peak electric field in the device is achieved, thereby improving the performance of the JBS diode 138. Additionally, the reduction in the peak electric field in the JBS diode 138 may allow the JBS diode 138 to utilize a low barrier height Schottky metal for the anode 148, such as Tantalum.

As will be appreciated by those of ordinary skill in the art, the JBS diode 138 shown in FIG. 21 represents a single cell of a semiconductor structure, which may include a large number of JBS diodes, each laterally tiled adjacent to one another.

According to one embodiment, the substrate 140 is a heavily doped N layer with a doping concentration between 1e18 cm⁻³ and 1e20 cm⁻³, the drift layer 142 is an N-doped layer with a doping concentration between 1E14 cm⁻³ and 1.5E16 cm⁻³, and the spreading layer 144 is a heavily doped N layer with a doping concentration between 1E16 cm⁻³ and 5E16 cm⁻³. In additional embodiments, one or more of the drift layer 142 and the spreading layer 144 may have a graded doping concentration, such that the doping concentration of the layer changes throughout the depth of the layer. Each one of the junction barrier regions 146 may be a lightly doped P layer with a doping concentration between 5E17 cm⁻³ and 1E20 cm⁻³. The distance between the junction barrier regions 146 (W_{SCH}) may be between about 1.5 μm to about 3 μm. The width of each one of the junction barrier regions 146 (W_{JNC}) may be between 1 μm and 2 μm. The depth of the spreading layer 144 (D_{SPR}) may be between 1 μm and 4 μm. The depth of each one of the junction implants 146 (D_{NC}) may be less than 1 μm. Finally, the depth of the drift layer 142 (D_{DFT}) may be between 3 um and 250 um.

According to one embodiment, the anode 148 and the cathode 150 may include one or more of titanium, nickel, or tantalum. Those of ordinary skill in the art will appreciate that the anode 148 and cathode 150 may be formed of any suitable contact metal, all of which are contemplated herein.

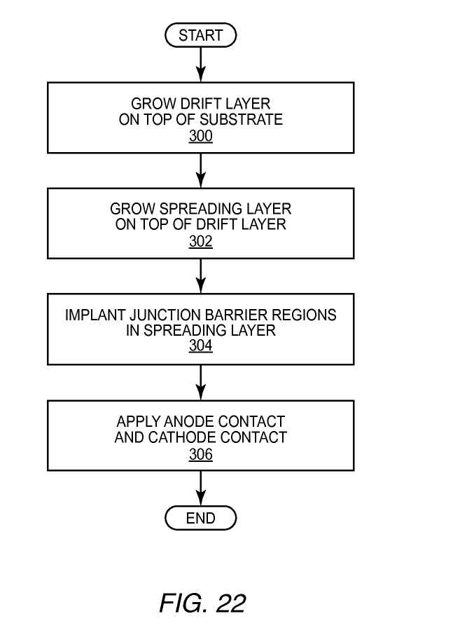

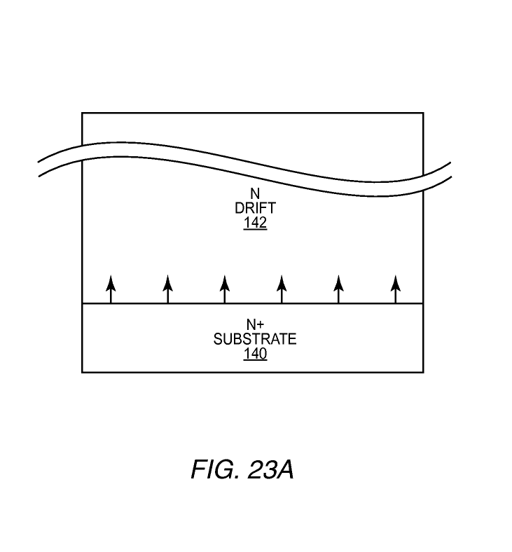

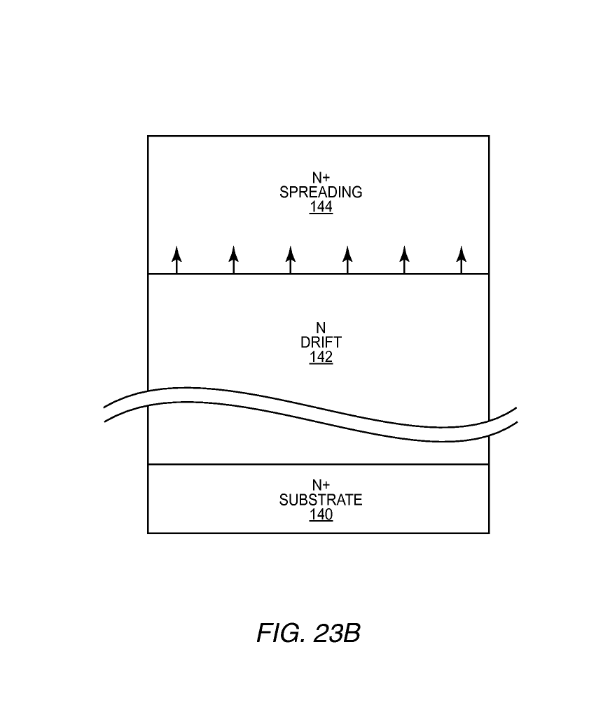

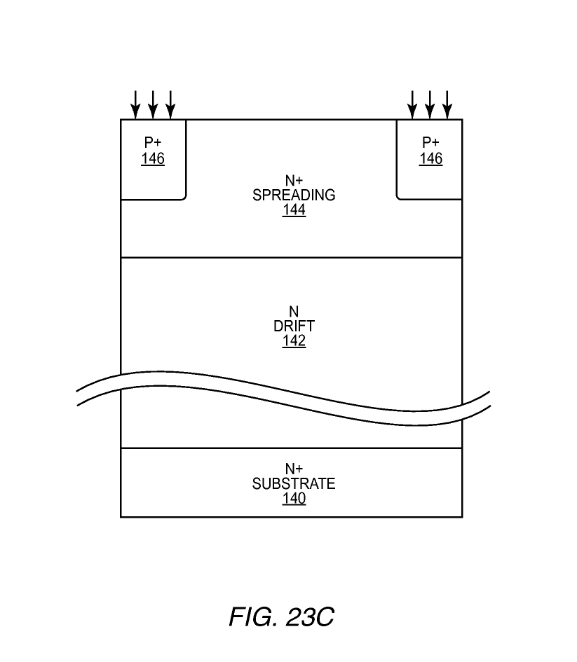

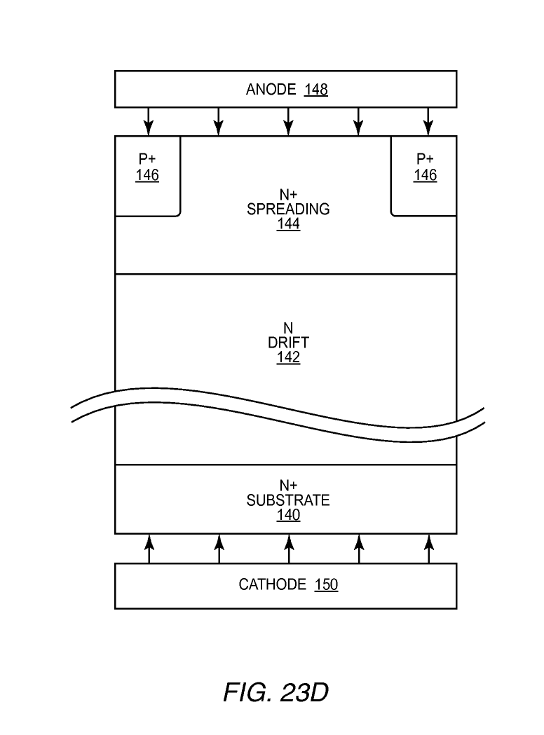

FIGS. 22 and 23A-23D illustrate a method for manufacturing the JBS diode 138 shown in FIG. 21. First, the drift layer 142 is grown on the substrate 140 (step 300 and FIG. 23A). In one exemplary embodiment, the drift layer 142 is grown on the substrate 140 by an epitaxial process, however, those of ordinary skill in the art will appreciate that numerous ways of providing the drift layer 142 exist, all of which are contemplated herein. The spreading layer 144 is then grown on the drift layer 142 opposite the substrate 140 (step 302 and FIG. 23B). Similar to the drift layer 142, the spreading layer 144 may also be provided by an epitaxial growth process or any other suitable method. The junction barrier regions 146 are then implanted in the surface of the spreading layer 144 opposite the drift layer 142 (step 304 and FIG. 23C). In one exemplary embodiment, the junction barrier regions 146 are provided by an ion implantation process, however, those of ordinary skill in the art will appreciate that numerous ways of providing the junction barrier regions 146 exist, all of which are contemplated herein. Finally, the anode 148 and the cathode 150 are provided on the surface of the spreading layer 144 opposite the drift layer 142 and the surface of the substrate 140 opposite the drift layer 142, respectively (step 306 and FIG. 23D).

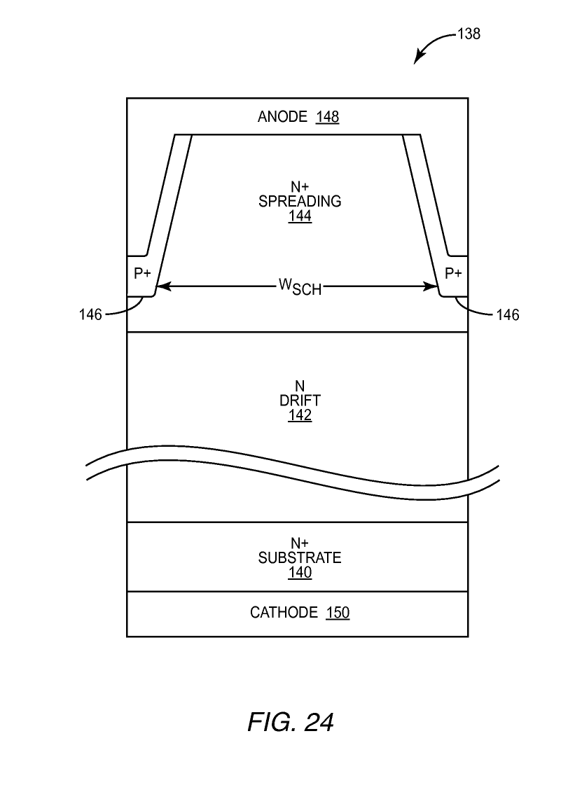

FIG. 24 shows the JBS diode 138 according to an additional embodiment of the present disclosure. The JBS diode 138 shown in FIG. 22 is substantially similar to that shown in FIG. 21, except that the JBS diode 138 includes a trench structure, in which the junction barrier regions 146 are recessed in the spreading layer 144, such that each one of the junction barrier regions 146 surround a portion of the anode 148, which protrudes into a trench formed in the spreading layer 144. According to one embodiment, the spreading layer 144 is selectively etched to form the one or more trenches, and the junction barrier regions 146 are implanted in the trenches. Using a trench structure for the JBS diode 138 allows for increased depth of the junction barrier regions 146 (D_{JNC}), while foregoing the need for a high-energy implantation process, which may otherwise result in significant damage to the crystalline structure of the JBS diode 138 and thereby degrade the performance thereof.

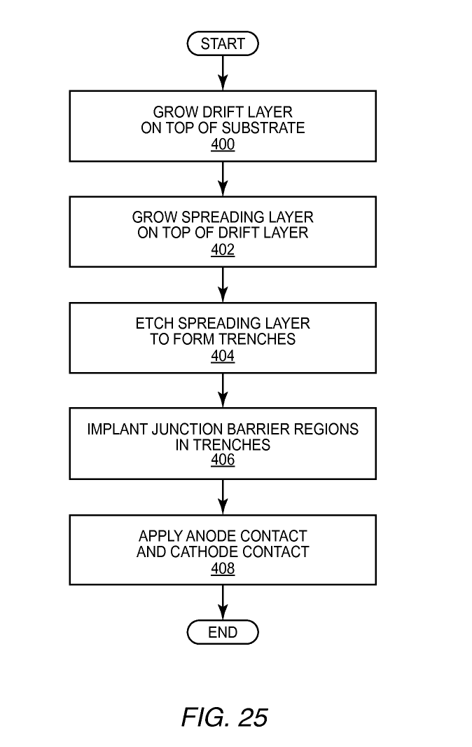

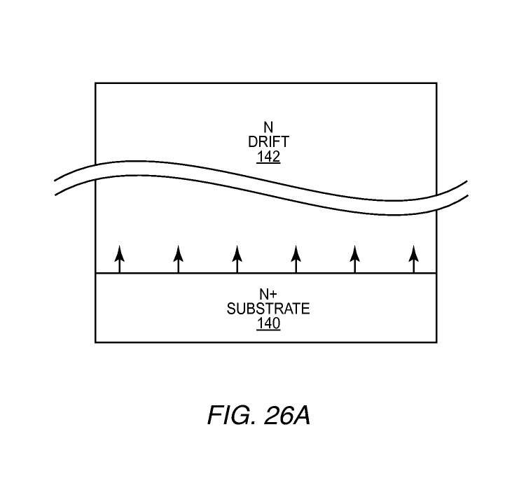

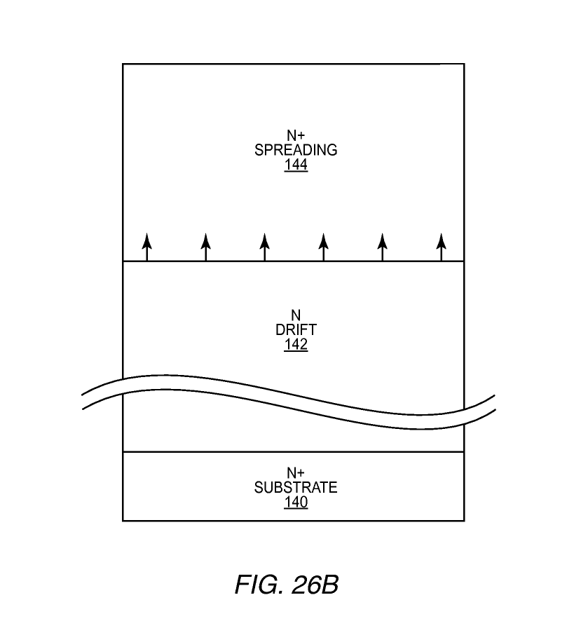

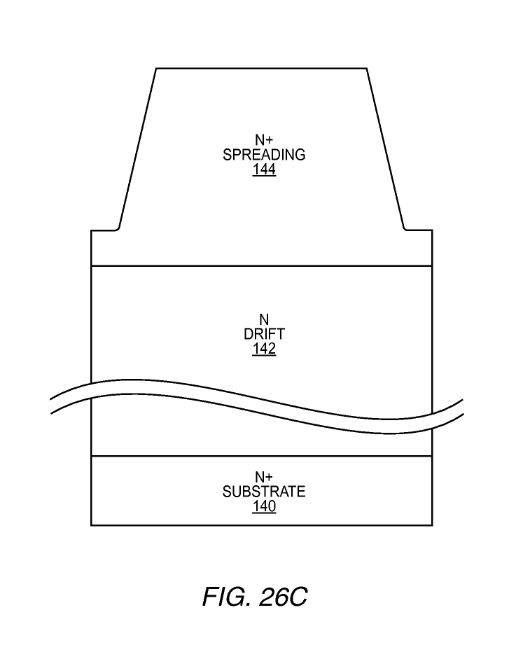

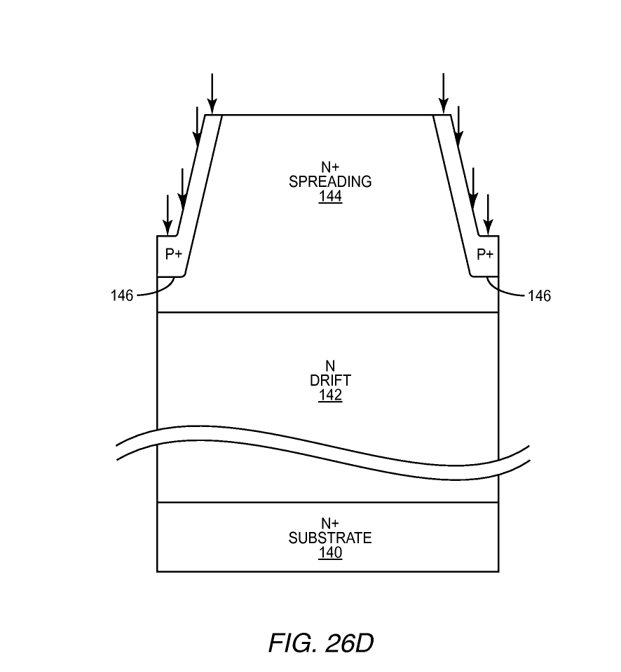

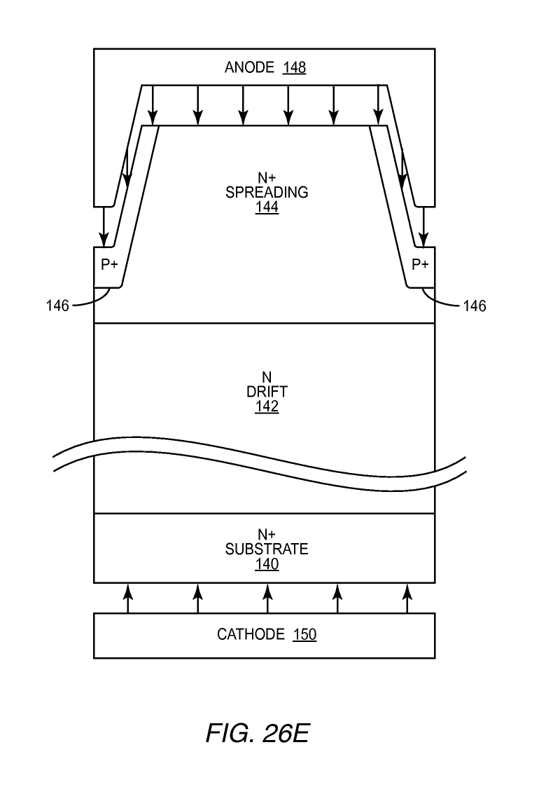

FIGS. 25 and 26A-26F illustrate a method for manufacturing the JBS diode 138 shown in FIG. 24. First, the drift layer 142 is grown on the substrate 140 (step 400 and FIG. 26A). In one exemplary embodiment, the drift layer 142 is grown on the substrate 140 by an epitaxial process, however, those of ordinary skill in the art will appreciate that numerous ways of providing the drift layer 142 exist, all of which are contemplated herein. The spreading layer 144 is then grown on the drift layer 142 opposite the substrate 140 (step 402 and FIG. 26B). Similar to the drift layer 142, the spreading layer 144 may also be provided by an epitaxial process or any other suitable method. The spreading layer 144 is then etched to form one or more trenches (step 404 and FIG. 26C). In one exemplary embodiment, the spreading layer 144 is etched by first applying a photo-resistive mask, then etching the portions of the spreading layer 144 exposed through the photo-resistive mask to form the trenches, however, those of ordinary skill in the art will appreciate that numerous ways of forming the trenches exist, all of which are contemplated herein. The junction barrier regions 146 are then implanted in the trenches (step 406 and FIG. 26D). In one exemplary embodiment, the junction barrier regions 146 are provided by an ion implantation process, however, those of ordinary skill in the art will appreciate that numerous ways of providing the junction barrier regions 146 exist, all of which are contemplated herein. Finally, the anode 148 and the cathode 150 are provided on the surface of the spreading layer 144 opposite the drift layer 142 and the surface of the substrate 140 opposite the drift layer 142, respectively (step 408 and FIG. 26E).

Those skilled in the art will recognize improvements and modifications to the preferred embodiments of the present disclosure. All such improvements and modifications are considered within the scope of the concepts disclosed herein and the claims that follow.

What is claimed is:

1. A junction barrier Schottky (JBS) diode comprising a substrate, a drift layer over the substrate, a spreading layer over the drift layer, and a pair of junction barrier regions in the spreading layer opposite the drift layer, wherein the on state resistance of the JBS diode is less than 54 mΩ-cm², and the leakage current of the JBS diode is less than 150 nA/cm² at a reverse voltage of 5.5 kV.

2. The JBS diode of claim 1 wherein each one of the pair of junction barrier regions is laterally separated from the other.

3. The JBS diode of claim 1 wherein each one of the pair of junction barrier regions is laterally separated from the other by a distance less than 3 μm.

4. The JBS diode of claim 3 wherein each one of the pair of junction barrier regions is laterally separated from the other by a distance greater than 1.5 μm.

5. The JBS diode of claim 1 wherein:
the substrate is a heavily doped N layer;
the drift layer is a lightly doped N layer; and
the spreading layer is a heavily doped N layer, such that the respective doping concentrations of each one of the substrate, the drift layer, and the spreading layer are different from one another.

6. The JBS diode of claim 5 wherein:
the doping concentration of the drift layer is between about 1E14 cm⁻³ and 1.5E16 cm⁻³; and
the doping concentration of the spreading layer is between about 1E16 cm⁻³ and 5E16 cm⁻³.

7. The JBS diode of claim 6 wherein each one of the pair of junction barrier regions is a heavily doped P region.

8. The JBS diode of claim 7 wherein each one of the pair of junction barrier regions has a doping concentration between about 5E17 cm⁻³ and 1E20 cm⁻³.

9. The JBS diode of claim 5 wherein the spreading layer comprises multiple layers.

10. The JBS diode of claim 9 wherein each layer of the spreading layer has a different doping concentration.

11. The JBS diode of claim 5 wherein the doping concentration of the spreading layer is graded.

12. The JBS diode of claim 1 wherein the JBS diode is a silicon carbide (SiC) device.

13. The JBS diode of claim 1 further comprising an anode contact over the surface of the spreading layer opposite the drift layer.

14. The JBS diode of claim 13 wherein the anode contact comprises a low barrier height Schottky metal.

15. The JBS diode of claim 14 wherein the anode contact comprises Tantalum.

16. A JBS diode comprising:
a substrate;
a drift layer over the substrate;
a spreading layer over the drift layer and including a pair of trenches, which extend from a surface of the spreading layer opposite the drift layer down into the spreading layer towards the drift layer;
a pair of junction implants in the trenches;
an anode contact over the surface of the spreading layer opposite the drift layer and in the trenches; and
a cathode contact over the surface of the substrate opposite the drift layer.

17. The JBS diode of claim 16 wherein each one of the pair of junction barrier regions is laterally separated from the other.

18. The JBS diode of claim 16 wherein each one of the pair of junction barrier regions is laterally separated from the other by a distance less than 3 μm.

19. The JBS diode of claim 18 wherein each one of the pair of junction barrier regions is laterally separated from the other by a distance greater than 1.5 μm.

20. The JBS diode of claim 16 wherein:
the substrate is a heavily doped N layer;
the drift layer is a lightly doped N layer; and
the spreading layer is a heavily doped N layer, such that the respective doping concentrations of each one of the substrate, the drift layer, and the spreading layer are different from one another.

21. The JBS diode of claim 20 wherein:
the doping concentration of the drift layer is between about 1E14 cm⁻³ and 1.5E16 cm⁻³; and
the doping concentration of the spreading layer is between about 1E16 cm⁻³ and 5E16 cm⁻³.

22. The JBS diode of claim 21 wherein each one of the pair of junction barrier regions is a heavily doped P region.

23. The JBS diode of claim 22 wherein each one of the pair of junction barrier regions has a doping concentration between about 5E17 cm⁻³ and 1E20 cm⁻³.

24. The JBS diode of claim 20 wherein the spreading layer comprises multiple layers.

25. The JBS diode of claim 24 wherein each layer of the spreading layer has a different doping concentration.

26. The JBS diode of claim 20 wherein the doping concentration of the spreading layer is graded.

27. The JBS diode of claim 16 wherein the JBS diode is a silicon carbide (SiC) device.

28. The JBS diode of claim 16 further comprising an anode contact over the surface of the spreading layer opposite the drift layer.

29. The JBS diode of claim 28 wherein the anode contact comprises a low barrier height Schottky metal.

30. The JBS diode of claim 29 wherein the anode contact comprises Tantalum.

31. A method of manufacturing a JBS diode comprising:
growing a drift layer on a substrate;
growing a spreading layer over the drift layer;
etching a pair of trenches in the spreading layer opposite the drift layer, such that the pair of trenches extend into the spreading layer towards the drift layer;
implanting a pair of junction implants in the trenches;
providing an anode contact over the surface of the spreading layer opposite the drift layer and in the trenches; and
providing a cathode contact over a surface of the substrate opposite the drift layer.

32. The method of claim 31 wherein each one of the pair of junction barrier regions is laterally separated from the other.

33. The method of claim 31 wherein:
the substrate is a heavily doped N layer;
the drift layer is a lightly doped N layer; and
the spreading layer is a heavily doped N layer, such that the respective doping concentrations of each one of the substrate, the drift layer, and the spreading layer are different from one another.

34. The method of claim 31 wherein:
the doping concentration of the drift layer is between about 6E15 cm⁻³ and 1.5E16 cm⁻³; and
the doping concentration of the spreading layer is between about 5E16 cm⁻³ and 2E17 cm⁻³.

35. The method of claim 33 wherein each one of the pair of junction barrier regions is a heavily doped P region.

36. The method of claim 35 wherein each one of the pair of junction barrier regions has a doping concentration between about 5E17 cm⁻³ and 1 E20 cm⁻³.

37. The method of claim 33 wherein the spreading layer comprises multiple layers.

38. The method of claim 37 wherein each layer of the spreading layer has a different doping concentration.

39. The method of claim 33 wherein the doping concentration of the spreading layer is graded.

40. The method of claim 31 wherein the JBS diode is a silicon carbide (SiC) device.

41. The JBS diode of claim 31 wherein the anode contact comprises a low barrier height Schottky metal.

42. The JBS diode of claim 41 wherein the anode contact comprises Tantalum.
